(19) United States
(12) Patent Application Publication
(10) Pub. No.: US 2022/0016869 A1
(43) Pub. Date: Jan. 20, 2022

(54) COVERS FOR ELECTRONIC DEVICES

(71) Applicant: Hewlett-Packard Development Company, L.P., Spring, TX (US)

(72) Inventors: Chien-Ting Lin, Taipei (TW); Kuan-Ting Wu, Taipei (TW); Chi Hao Chang, Taipei (TW)

(73) Assignee: Hewlett-Packard Development Company, L.P., Spring, TX (US)

(21) Appl. No.: 17/054,565

(22) PCT Filed: Mar. 27, 2019
(86) PCT No.: PCT/US2019/024218

§ 371 Date: Nov. 11, 2020

(51) Int. Cl. B32B 7/12; C09K 5/14; C08J 5/18; C09J 11/04; C09J 5/00; B32B 5/02; B32B 17/06; B32B 15/20; B32B 27/36; B32B 27/30; B32B 27/40; B32B 27/38; B32B 27/06

(52) U.S. Cl. CPC B32B 7/12; C09K 5/14; C08J 5/18; C09J 11/04; C09J 5/00; B32B 5/02; H05K 5/00; B32B 15/20; B32B 27/36; B32B 27/308; B32B 27/40; B32B 27/38; B32B 27/06; B32B 17/06

(57) ABSTRACT

The present disclosure is drawn to covers for electronic devices, coating sets for covers of electronic devices, and methods for making these covers. In one example, described herein is a cover for an electronic device comprising: a substrate; an adhesive layer on a surface of the substrate; a first thermally conductive layer on the adhesive layer; a first oxide layer on the first thermally conductive layer; an aluminum foil layer on the first oxide layer; a second oxide layer on the aluminum foil layer; and a second thermally conductive layer on the second oxide layer.

### BACKGROUND

The use of personal electronic devices of all types continues to increase. Cellular phones, including smartphones, have become nearly ubiquitous. Tablet computers have also become widely used in recent years. Portable laptop computers continue to be used by many for personal, entertainment, and business purposes. For portable electronic devices in particular, much effort has been expended to make these devices more useful and more powerful while at the same time making the devices smaller, lighter, and more durable. The aesthetic design of personal electronic devices is also of concern in this competitive market.

### BRIEF DESCRIPTION OF THE DRAWING

FIG. 1 is a cross-sectional view illustrating an example cover for an electronic device in accordance with examples of the present disclosure;

FIG. 2 is a cross-sectional view illustrating another example for a cover for an electronic device in accordance with examples of the present disclosure:

FIG. 3 is a cross-sectional view illustrating yet another example for a cover for an electronic device in accordance with examples of the present disclosure;

FIG. 4 is a cross-sectional view illustrating an example cover for an electronic device in accordance with examples of the present disclosure; and

FIG. 5 is a flowchart illustrating an example method of making a cover for an electronic device in accordance with examples of the present disclosure.

### DETAILED DESCRIPTION

In some examples, development of anodized aluminum composite heat spreader is described. The anodized aluminum composite heat spreader is developed by physical vapor deposition (PVD) of graphene and/or graphite layers sandwiched with anodized aluminum foil layers to achieve heat dissipation and obtain low skin temperature on portable electronic devices such as laptops and tablet personal computers. Low thermal conductivity of anodized aluminum layer can act as a heat transfer buffer layer to slow down heat transfer and work to lower skin temperature on laptop or tablet cover surface.

“Skin temperature,” as used herein, refers to the electronic device surface temperature.

In some examples, anodized aluminum composite heat spreader can be developed by PVD of graphene and/or graphite layers sandwiched with anodized aluminum layers. In some examples, it has been demonstrated that a thermal conductivity of from about 400 W/mK to about 2,000 W/mK can be achieved by the afore-described heat spreader when measured in an X and Y direction on the graphene and/or graphite layer. In some examples, aluminum anodized layer, acts as heat transfer buffer layer to slow down heat transfer with lower thermal conductivity of from about 0.53 W/mK to about 1.62 W/mK to avoid high skin temperature on the laptop cover surface.

In some examples, the anodized aluminum layer, which can be porous, can provide advantages including: acting as a protection layer enhancing the bonding ability with PVD graphene and/or graphite layers; eliminating or reducing hot spot issues; extending product lifetime including the life of a liquid crystal display (LCD) panel, light emitting diodes (LED), central processing units (CPU), and/or battery due to reduced hot spot issues: improving information loading speed and power efficiency; and reducing the risk of battery instability issues.

The present disclosure is drawn to covers for electronic devices, coating sets for covers of electronic devices, and methods for making these covers.

In some examples, disclosed herein is a cover for an electronic device comprising: a substrate; an adhesive layer on a surface of the substrate; a first thermally conductive layer on the adhesive layer; a first oxide layer on the first thermally conductive layer; an aluminum foil layer on the first oxide layer; a second oxide layer on the aluminum foil layer; and a second thermally conductive layer on the second oxide layer.

In some examples, the cover can further comprise:

a thermoplastic polymer layer on the second thermally conductive layer.

In some examples, the thermoplastic polymer layer has a thickness of from about 5 μm to about 15 μm and comprises polyethylene terephthalate.

In some examples, the adhesive layer comprises acrylic-based adhesives, natural rubber-based adhesives, styrene-butadiene rubber-based adhesives, styrenic block copolymer based adhesives, silicone-based adhesive, or combinations thereof.

In some examples, the adhesive layer comprises from about 0.01 wt % to about 0.3 wt % thermally conductive particles, selected from the group of nano or micro particles of graphene, carbon nanotube particles, nano or micro particles of graphite, nano or micro particles of aluminum, nano or micro particles of copper, nano or micro particles of silver, nano or micro particles of silicon, nano or micro particles of gold, nano or micro particles of diamond, or combinations thereof, based on a total weight of the adhesive layer.

In some examples, the substrate comprises plastic, carbon fiber, glass, metal, a composite, or a combination thereof.

In some examples, the first thermally conductive layer and the second thermally conductive layer are the same and comprise graphite, graphene, or a combination thereof.

In some examples, the first thermally conductive layer and the second thermally conductive layer are different and comprise graphite, graphene, or a combination thereof.

In some examples, the first oxide layer and the second oxide layer are the same and comprise anodized aluminum.

In some examples, disclosed is a coating set for a cover of an electronic device comprising a substrate: an adhesive layer on a surface of the substrate; a first thermally conductive layer on the adhesive layer; a first oxide layer on the first thermally conductive layer; an aluminum foil layer on the first oxide layer; a second oxide layer on the aluminum foil layer; a second thermally conductive layer on the second oxide layer; and a thermoplastic polymer layer on the second thermally conductive layer, wherein the first thermally conductive layer and the second thermally conductive layer are same or different and each comprises graphite, graphene, or a combination thereof.

In some examples, disclosed is an electronic device comprising the coating set described above.

In some examples, the adhesive layer has a thickness of from about 5 μm to about 30 μm.

In some examples, the first thermally conductive layer and the second thermally conductive layer each have a thickness of about 5 μm to about 500 μm.

In some examples, the first oxide layer and the second oxide layer each have a thickness of about 3 μm to about 15 μm.

In some examples, the aluminum foil layer has thickness of about 10 μm to about 100 μm.

In some examples, disclosed herein is a method of making an electronic device cover including a substrate, the method comprising: applying an adhesive layer on a surface of the substrate; applying a first thermally conductive layer on the adhesive layer; applying a first oxide layer on the first thermally conductive layer; applying an aluminum foil layer on the first oxide layer; applying a second oxide layer on the aluminum foil layer; applying a second thermally conductive layer on the second oxide layer; and applying a thermoplastic polymer layer on the second thermally conductive layer.

### Covers for Electronic Devices

As used herein, “cover” refers to the exterior shell or housing of an electronic device. In other words, the cover contains the internal electronic components of the electronic device. The cover is an integral part of the electronic device. The layers or coating set described here are adherable to a cover of electronic devices, but in some examples, they are actually adhered to the cover of the electronic device. The term “cover” is not meant to refer to the type of removable protective cases that are often purchased separately from an electronic device (especially smartphones and tablets) and placed around the exterior of the electronic device. However, the layers or coating set described herein may be adhered to other surfaces besides covers for electronic devices, e.g., to removable protective cases or other surfaces.

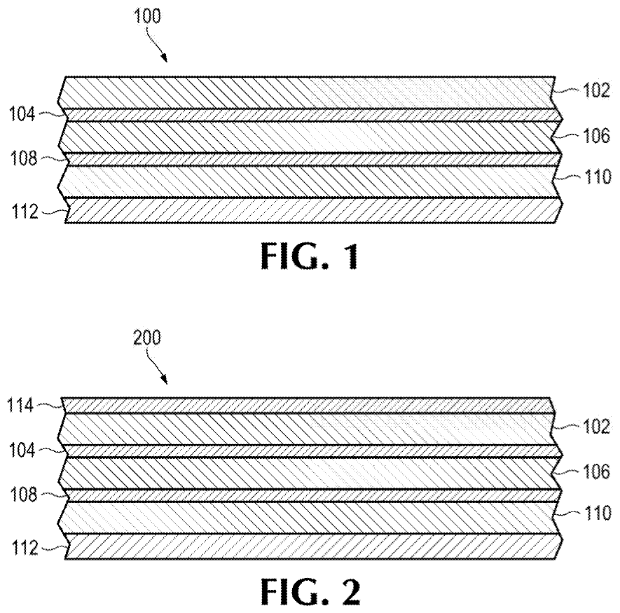

With the above description in mind, FIG. 1 shows a cross-sectional view of an example cover (100) for an electronic device in accordance with an example of the present disclosure. The cover (100) for an electronic device comprises: a substrate (not shown); an adhesive layer on a surface of the substrate (112); a first thermally conductive layer (with graphene) on the adhesive layer (110); a first oxide layer on the first thermally conductive layer (108); an aluminum foil layer on the first oxide layer (106); a second oxide layer on the aluminum foil layer (104); and a second thermally conductive layer (with graphene) on the second oxide layer (102).

With the above description in mind, FIG. 2 shows a cross-sectional view of an example cover (200) for an electronic device in accordance with an example of the present disclosure. The cover (200) for an electronic device comprises: a substrate (not shown); an adhesive layer on a surface of the substrate (112); a first thermally conductive layer (with graphene) on the adhesive layer (110); a first oxide layer on the first thermally conductive layer (108); an aluminum foil layer on the first oxide layer (106); a second oxide layer on the aluminum foil layer (104); a second thermally conductive layer (with graphene) on the second oxide layer (102); and a thermoplastic polymer layer on the second thermally conductive layer (114).

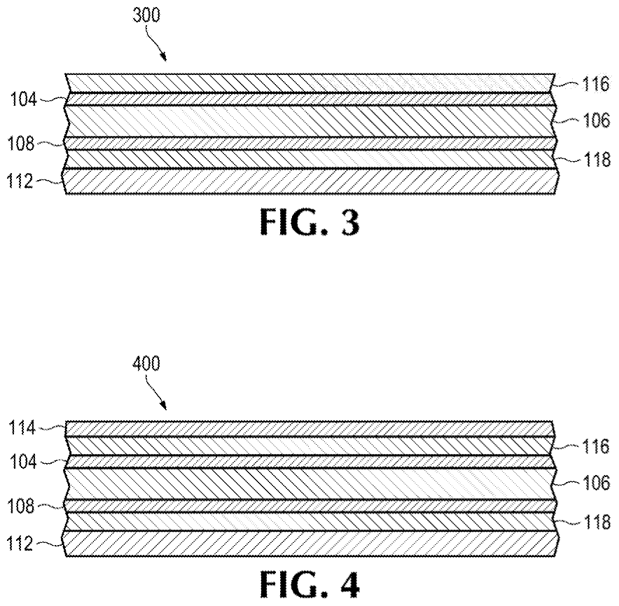

With the above description in mind, FIG. 3 shows a cross-sectional view of an example cover (300) for an electronic device in accordance with an example of the present disclosure. The cover (300) for an electronic device comprises: a substrate (not shown); an adhesive layer on a surface of the substrate (112); a first thermally conductive layer (with graphite) on the adhesive layer (118); a first oxide layer on the first thermally conductive layer (108); an aluminum foil layer on the first oxide layer (106); a second oxide layer on the aluminum foil layer (104); and a second thermally conductive layer (with graphite) on the second oxide layer (116).

With the above description in mind, FIG. 4 shows a cross-sectional view of an example cover (400) for an electronic device in accordance with an example of the present disclosure. The cover (400) for an electronic device comprises: a substrate (not shown); an adhesive layer on a surface of the substrate (112); a first thermally conductive layer (with graphite) on the adhesive layer (118); a first oxide layer on the first thermally conductive layer (108); an aluminum foil layer on the first oxide layer (106); a second oxide layer on the aluminum foil layer (104); a second thermally conductive layer (with graphite) on the second oxide layer (116); and a thermoplastic polymer layer on the second thermally conductive layer (114).

It is to be understood that the thermally conductive layers can comprise, graphene, graphite, or combinations thereof.

It is noted that when discussing coating sets/layers, covers for electronic devices, or methods of making the covers for electronic devices, such discussions can be considered applicable to one another whether or not they are explicitly discussed in the context of that example. It is also understood that terms used herein will take on their ordinary meaning in the relevant technical field unless specified otherwise. In some instances, there are terms defined more specifically throughout or included at the end of the present disclosure, and thus, these terms are supplemented as having a meaning described herein.

In further detail, it noted that the spatial relationship between layers is often described herein as positioned or applied “on” or “over” another layer. These terms do not infer that this layer is positioned directly in contact with the layer to which it refers, but could have intervening layers therebetween. That being stated, a layer described as being positioned on or over another layer can be positioned directly on that other layer, and thus such a description finds support herein for being positioned directly on the referenced layer.

### Rigid Substrate

In some examples, the substrate comprises plastic, carbon fiber, glass, metal, a composite, or a combination thereof.

In some examples, the rigid substrate of the cover for an electronic device can include plastic, carbon fiber, glass, metal, a composite, or a combination thereof. In certain examples, the substrate can include a light metal such as aluminum, magnesium, titanium, lithium, niobium, or an alloy thereof. In some examples, alloys of these metals can include additional metals, such as bismuth, copper, cadmium, iron, thorium, strontium, zirconium, manganese, nickel, lead, silver, chromium, silicon, tin, gadolinium, yttrium, calcium, antimony, zinc, cerium, lanthanum, or others. In a particular example, the substrate can be pure magnesium or an alloy including 99% magnesium or greater. In another particular example, the substrate can be made of an alloy including magnesium and aluminum. In a particular example, the substrate can be made from AZ31 alloy or AZ91 alloy.

In further examples, the substrate can include carbon fiber. In particular, the substrate can be a carbon fiber composite. The carbon fiber composite can include carbon fibers in a plastic material such as a thermoset resin or a thermoplastic polymer. Non-limiting examples of the polymer can include epoxies, polyesters, vinyl esters, and polyamides.

In various examples, the substrate can be formed by molding, casting, machining, bending, working, or another process. In certain examples, the substrate can be a chassis for an electronic device that is milled from a single block of metal or metal alloy. In other examples, an electronic device chassis, can be made from multiple panels. As an example, laptops sometimes include four separate pieces forming the chassis or cover of the laptop, with the electronic components of the laptop protected inside the chassis. The four separate pieces of the laptop chassis are often designated as cover A (back cover of the monitor portion of the laptop), cover B (front cover of the monitor portion), cover C (top cover of the keyboard portion) and cover D (bottom cover of the keyboard portion). In certain examples, one of these covers or more than one of these covers can include metal, metal alloy, carbon fiber, glass, plastic, and so on. These covers can be made by machining, casting, molding, bending, or by other forming methods. Other types of electronic device covers can also be the substrate referred to above, such as a smartphone, tablet, or television cover. These substrates can be made using the same forming methods.

The substrate is not particularly limited with respect to thickness. However, when used as a panel for an electronic device, such as for a housing or chassis, the thickness of the substrate chosen, the density of the material (for purposes of controlling weight, for example), the hardness of the material, the malleability of the material, the material aesthetic, etc., can be selected as appropriate for a specific type of electronics device, e.g., lightweight materials and thickness chosen for housings where lightweight properties may be commercially competitive, heavier more durable materials chosen for housings where more protection may be useful, etc. To provide some examples, the thickness of the substrate can be from about 0.5 mm to about 2 cm, from about 1 mm to about 1.5 cm, from about 1.5 mm to about 1.5 cm, from about 2 mm to about 1 cm, from about 3 mm to about 1 cm, from about 4 mm to about 1 cm, or from about 1 mm to about 5 mm, though thicknesses outside of these ranges can be used.

In further examples, a rigid substrate may include more than one type of material. In certain examples, a substrate can include a plastic portion formed by insert molding. For example, a substrate can have a metal portion or a carbon fiber portion or a glass portion and an insert molded plastic portion. Insert molding involves placing the substrate portion into a mold, where a plastic material is then injection molded in the mold around the metal, carbon fiber, or glass. In some cases, the metal, carbon fiber, or glass substrate can include an undercut shape and the molten plastic can flow into the undercut during injection molding. When the plastic hardens, the undercut can provide a strong connection between the plastic and the other portion of the substrate.

In still further examples, the rigid substrate can include a metal having a micro-arc oxidation layer on a surface thereof. Micro-arc oxidation, also known as plasma electrolytic oxidation, is an electrochemical process where the surface of a metal is oxidized using micro-discharges of compounds on the surface of the substrate when immersed in a chemical or electrolytic bath, for example. The electrolytic bath may include predominantly water with about 1 wt % to about 5 wt % electrolytic compound(s), e.g., alkali metal silicates, alkali metal hydroxide, alkali metal fluorides, alkali metal phosphates, alkali metal aluminates, the like, and combinations thereof. The electrolytic compounds may likewise be included at from about 1.5 wt % to about 3.5 wt %, or from about 2 wt % to about 3 wt %, though these ranges are not considered limiting. In one example, a high-voltage alternating current can be applied to the substrate to create plasma on the surface of the substrate. In this process, the substrate can act as one electrode immersed in the electrolyte solution, and the counter electrode can be any other electrode that is also in contact with the electrolyte. In some examples, the counter electrode can be an inert metal such as stainless steel. In certain examples, the bath holding the electrolyte solution can be conductive and the bath itself can be used as the counter electrode. A high direct current or alternating voltage can be applied to the substrate and the counter electrode. In some examples, the voltage can be 200 V or higher, such as about 200 V to about 600 V, about 250 V to about 600 V, about 250 V to about 500 V, or about 200 V to about 300 V. Temperatures can be from about 20° C. to about 40° C., or from about 25° C. to about 35° C., for example, though temperatures outside of these ranges can be used. This process can oxidize the surface to form an oxide layer from the substrate material. Various metal or metal alloy substrates can be used, including aluminium, titanium, lithium, magnesium, and/or alloys thereof, for example. The oxidation can extend below the surface to form thick layers, as thick as 30 μm or more. In some examples the oxide layer can have a thickness from about 1 μm to about 25 μm, from about 1 μm to about 22 μm, or from about 2 μm to about 20 μm. Thickness can likewise be from about 2 μm to about 15 μm, from about 3 μm to about 10 μm, or from about 4 μm to about 7 μm. The oxide layer can, in some instances, enhance the mechanical, wear, thermal, dielectric, and corrosion properties of the substrate. The electrolyte solution can include a variety of electrolytes, such as a solution of potassium hydroxide. In some examples, the rigid substrate can include a micro-arc oxidation layer on one side, or on both sides.

### Adhesive Layers

The adhesive layer comprises acrylic-based adhesives, natural rubber-based adhesives, styrene-butadiene rubber-based adhesives, styrenic block copolymer based adhesives, silicone-based adhesive, or combinations thereof.

The acrylic-based adhesives, natural rubber-based adhesives, styrene-butadiene rubber-based adhesives, styrenic block copolymer based adhesives, silicone-based adhesive, or combinations thereof can be present in the adhesive layer in amounts of at least about 90 wt % based on the total n weight of the adhesive layer, or at least about 95 wt %, or at least about 99 wt %. The balance of the adhesive layer can include thermally conductive particles, fillers, and/or stabilizers.

In some examples, a wide variety of fillers can be added to the adhesive layer. Suitable fillers include calcium carbonate, clays, talcs, silica, zinc oxide, titanium dioxide, or combinations thereof. The amount of filler usually is in the range of from about 0 wt % to about 15% wt % based on the total weight of the adhesive layer. Stabilizers are typically added to the adhesive layer in order to protect the polymers against heat degradation and oxidation. The amount of stabilizer usually is in the range of from about 0 wt % to about 5% wt % based on the total weight of the adhesive layer.

The adhesive layer comprises from about 0.01 wt % to about 0.3 wt % thermally conductive particles selected from the group of nano or micro particles of graphene, carbon nanotube particles, nano or micro particles of graphite, nano or micro particles of aluminum, nano or micro particles of copper, nano or micro particles of silver, nano or micro particles of silicon, nano or micro particles of gold, nano or micro particles of diamond, or combinations thereof, based on a total weight of the adhesive layer.

It is to be understood that “nano” sized particles include average sizes of from about 1 nm to about 1000 nm. It is to be further understood that “micro” sized particles include average sizes of from about 1 μm to about 500 μm.

In some examples, the adhesive layer can comprise from about 0.01 wt % to about 0.3 wt % thermally conductive particles based on the total weight of the adhesive layer, or from about 0.05 wt % to about 0.2 wt %, or less than about 1 wt %, or less than about 0.5 wt %, or less than about 0.4 wt %, or less than about 0.3 wt %, or less than about 0.2 wt %, or less than about 0.1 wt %, or less than about 0.05 wt %.

The adhesive layer has a thickness of from about 5 μm to about 30 μm, or less than about 50 μm, or less than about 40 μm, or less than about 30 μm, or less than about 20 μm, or less than about 10 μm.

### Thermally Conductive Layers

The first thermally conductive layer and the second thermally conductive layer are the same and comprise graphite, graphene, or a combination thereof.

The first thermally conductive layer and the second thermally conductive layer are different and comprise graphite, graphene, or a combination thereof.

The graphite and graphene particles can have an average size of from about 1 μm to about 100 μm, or less than about 50 μm, or less than about 40 μm, or less than about 30 μm, or less than about 20 μm, or less than about 10 μm.

In some examples, the first thermally conductive layer and the second thermally conductive layer comprise graphene and/or graphite alone or in combination with some fillers and/or stabilizers.

In some examples, the first thermally conductive layer and the second thermally conductive layer can further include polyacrylic, polymethacrylic, polyethylene terephthalate, polyimide, polyurethane, polycarbonate, polyvinyl chloride, or a combination thereof.

In some examples the first thermally conductive layer and the second thermally conductive layer can further include a wide variety of fillers and/or stabilizers. Suitable fillers can include calcium carbonate, clays, talcs, silica, zinc oxide, titanium dioxide, or combinations thereof. The amount of filler usually is in the range of from about 0 wt % to about 15% wt % based on the total weight of the thermally conductive layer. Stabilizers can be typically added to the first thermally conductive layer and/or the second thermally conductive layer to protect the polymers against heat degradation and oxidation. The amount of stabilizer usually is in the range of from about 0 wt % to about 5% wt % based on the total weight of the thermally conductive layer.

The first thermally conductive layer and the second thermally conductive layer each have a thickness of from about 5 μm to about 500 μm, from about 15 μm to about 450 μm, or from about 25 μm to about 400 μm, or from about 35 μm to about 350 μm, or from about 45 μm to about 300 μm, or from about 55 μm to about 250 μm, or from about 65 μm to about 200 μm, or from about 75 μm to about 150 μm, or from about 85 μm to about 100 μm.

### Oxide Layers

The first oxide layer and the second oxide layer are the same and comprise anodized aluminum.

In some examples, anodized aluminum can prepared by placing aluminum in an acid bath; anodizing the aluminum in an anodizing acid bath by passing a current there through to form a porous oxide layer on an exterior surface of the aluminum. In some examples, the acid bath can be warmed to from about 50° C. to about 100° C. for treating the metal substrate. In another example, the current passed there through can range from about 10V to about 20V.

The first oxide layer and the second oxide layer each have a thickness of from about 3 μm to about 15 μm, or less than about 20 μm, or less than about 15 μm, or less than about 10 μm, or less than about 8 μm, or less than about 5 μm.

### Aluminum Foil Layers

In some examples, the aluminum foil layer has a thickness of about 10 μm to about 100 μm, or less than about 100 μm, or less than about 90 μm, or less than about 80 μm, or less than about 70 μm, or less than about 60 μm, or less than about 50 μm, or less than about 40 μm, or less than about 30 μm, or less than about 20 μm.

In some examples, the aluminum foil can substantially comprise aluminum with traces of other metals such as carbon, silicon, and oxides thereof.

### Thermoplastic Polymer Layer(s)

In some examples, the thermoplastic polymer layer has a thickness of from about 5 μm to about 15 μm and comprises polyethylene terephthalate.

In some examples, the thermoplastic polymer layer has a thickness of less than about 20 μm, or less than about 15 μm, or less than about 10 μm.

In some examples, the thermoplastic polymer layer can comprise a transparent resin with a three dimensional pattern molded into the top surface of the layer. In some examples, the thermoplastic layer can comprise a radiation-curable resin such as polyethylene terephthalate (polyester), poly(meth)acrylic, polyurethane, urethane (meth)acrylate, (meth)acrylic (meth)acrylate, epoxy (meth)acrylate, or a combination thereof.

In some examples, the thermoplastic polymer layer can include polyacrylic, polymethacrylic, polyethylene terephthalate, polyimide, polyurethane, polycarbonate, polyvinyl chloride, or a combination thereof.

In some examples, a wide variety of fillers can be added to the thermoplastic layer. Suitable fillers include calcium carbonate, clays, talcs, silica, zinc oxide, titanium dioxide, or combinations thereof. The amount of filler usually is in the range of from about 0 wt % to about 15% wt % based on the total weight of the thermoplastic layer. Stabilizers are typically added to the thermoplastic layer in order to protect the polymers against heat degradation and oxidation. The amount of stabilizer usually is in the range of from about 0 wt % to about 5% wt % based on the total weight of the thermoplastic layer.

### Methods of Making Covers for Electronic Devices

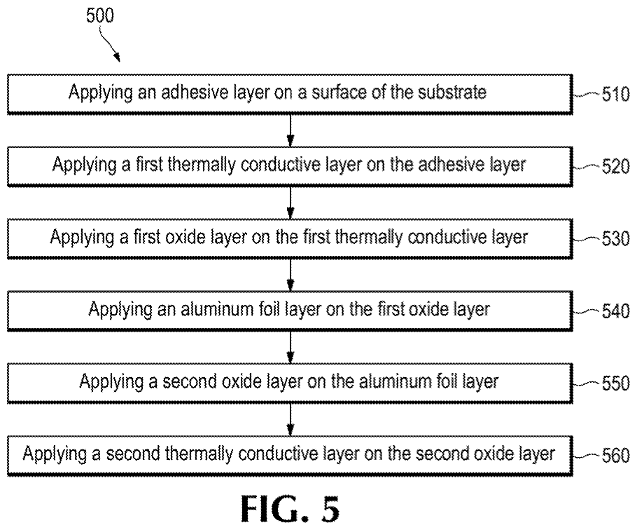

The present disclosure also extends to methods of making covers for electronic devices. FIG. 5 is a flowchart showing an example method 500 of making an electronic device cover including a substrate. The method includes: applying an adhesive layer on a surface of the substrate (510); applying a first thermally conductive layer on the adhesive layer (520); applying a first oxide layer on the first thermally conductive layer (530); applying an aluminum foil layer on the first oxide layer (540) applying a second oxide layer on the aluminum foil layer (550); and applying a second thermally conductive layer on the second oxide layer (560).

In some examples, the method can further comprise applying a thermoplastic polymer layer on the second thermally conductive layer (not shown in FIG. 5).

In some examples, curing of curable polymers in one or more layers can be carried out by applying UV radiation. Curing can include exposing a layer to radiation energy at an intensity from about 500 mJ/cm² to about 2,000 mJ/cm² or from about 700 mJ/cm² to about 1,300 mL/cm². The layer can be exposed to the radiation energy for a curing time from about 5 seconds to about 30 seconds, or from about 10 seconds to about 30 seconds. In other examples, curing can include heating the protective coating layer at a temperature from about 50° C. to about 80° C. or from about 50° C. to about 60° C. or from about 60° C. to about 80° C. The layer can be heated for a curing time from about 5 minutes to about 40 minutes, or from about 5 minutes to about 10 minutes, or from about 20 minutes to about 40 minutes.

In further examples, the methods of depositing layers to make the cover can be continuous methods, such as roll-to-roll methods. In one such example, a roller of, for example, a thermoplastic polymer layer can be fed from a roll through equipment suitable to add this and/or other layers onto a cover. The devices that can be used in applying and/or forming layers includes but is not limited to coating devices, drying devices, curing devices, molds, PVD devices, or combinations thereof.

“Out molding” as used herein refers to a process in which an individual layer, such as a sheet, is placed in a stationary mold to mold a three dimensional pattern into the clear thermoplastic polymer layer. Thus, this is more of a batch process than a continuous process as a single sheet is molded at one time.

It is noted that, as used in this specification and the appended claims, the singular forms “a,” “an,” and “the” include plural, referents unless the content clearly dictates otherwise.

The term “about” as used herein, when referring to a numerical value or range, allows for a degree of variability in the value or range, for example, within 5% or other reasonable added range breadth of a stated value or of a stated limit of a range. The term “about” when modifying a numerical range is also understood to include the exact numerical value indicated, e.g., the range of about 1 wt % to about 5 wt % includes 1 wt % to 5 wt % as an explicitly supported sub-range.

As used herein, “average particle size” refers to a number average of the diameter of the particles for spherical particles, or a number average of the volume equivalent sphere diameter for non-spherical particles. The volume equivalent sphere diameter is the diameter of a sphere having the same volume as the particle. Average particle size can be measured using a particle analyzer such as the Mastersizer™ 3000 available from Malvern Panalytical. The particle analyzer can measure particle size using laser diffraction. A laser beam can pass through a sample of particles and the angular variation in intensity of light scattered by the particles can be measured. Larger particles scatter light at smaller angles, while small particles scatter light at larger angles. The particle analyzer can then analyze the angular scattering data to calculate the size of the particles using the Mie theory of light scattering. The particle size can be reported as a volume equivalent sphere diameter.

As used herein, a plurality of items, structural elements, compositional elements, and/or materials may be presented in a common list for convenience. However, these lists should be construed as though the individual members of the list are individually identified as a separate and unique member. Thus, no individual member of such list should be construed as a de facto equivalent of any other member of the same list solely based on their presentation in a common group without indications to the contrary.

Concentrations, dimensions, amounts, and other numerical data may be presented herein in a range format. It is to be understood that such range format is used merely for convenience and brevity and should be interpreted flexibly to include the numerical values explicitly recited as the limits of the range, and also to include all the individual numerical values or sub-ranges encompassed within that range as if individual numerical values and sub-ranges are explicitly recited. For example, a layer thickness from about 0.1 μm to about 0.5 μm should be interpreted to include the explicitly recited limits of 0.1 μm to 0.5 μm, and to include thicknesses such as about 0.1 μm and about 0.5 μm, as well as subranges such as about 0.2 μm to about 0.4 μm, about 0.2 μm to about 0.5 μm, about 0.1 μm to about 0.4 μm etc.

The following illustrates an example of the present disclosure. However, it is to be understood that the following is illustrative of the application of the principles of the present disclosure. Numerous modifications and alternative compositions, methods, and systems may be devised without departing from the spirit and scope of the present disclosure. The appended claims are intended to cover such modifications and arrangements.

What is claimed is:

1. A cover for an electronic device comprising:
a substrate;
an adhesive layer on a surface of the substrate;
a first thermally conductive layer on the adhesive layer;
a first oxide layer on the first thermally conductive layer;
an aluminum foil layer on the first oxide layer;
a second oxide layer on the aluminum foil layer; and
a second thermally conductive layer on the second oxide layer.

2. The cover of claim 1 further comprising:
a thermoplastic polymer layer on the second thermally conductive layer.

3. The cover of claim 2, wherein the thermoplastic polymer layer has thickness of from about 5 μm to about 15 μm and comprises polyethylene terephthalate.

4. The cover of claim 1, wherein:
the adhesive layer comprises acrylic-based adhesives, natural rubber-based adhesives, styrene-butadiene rubber-based adhesives, styrenic block copolymer based adhesives, silicone-based adhesive, or combinations thereof, and
the adhesive layer comprises from about 0.01 wt % to about 0.3 wt % thermally conductive particles selected from the group of nano or micro particles of graphene, carbon nanotube particles, nano or micro particles of graphite, nano or micro particles of aluminum, nano or micro particles of copper, nano or micro particles of silver, nano or micro particles of silicon, nano or micro particles of gold, nano or micro particles of diamond, or combinations thereof, based on a total weight of the adhesive layer.

5. The cover of claim 1, wherein the substrate comprises plastic, carbon fiber, glass, metal, a composite, or a combination thereof.

6. The cover of claim 1, wherein the first thermally conductive layer and the second thermally conductive layer are the same and comprise graphite, graphene, or a combination thereof.

7. The cover of claim 1, wherein the first thermally conductive layer and the second thermally conductive layer are different and comprise graphite, graphene, or a combination thereof.

8. The cover of claim 1, wherein the first oxide layer and the second oxide layer are the same and comprise anodized aluminum.

9. A coating set for a cover of an electronic device comprising:
a substrate;
an adhesive layer on a surface of the substrate;
a first thermally conductive layer on the adhesive layer;
a first oxide layer on the first thermally conductive layer;
an aluminum foil layer on the first oxide layer;
a second oxide layer on the aluminum foil layer;
a second thermally conductive layer on the second oxide layer; and
a thermoplastic polymer layer on the second thermally conductive layer,
wherein the first thermally conductive layer and the second thermally conductive layer are same or different and each comprise graphite, graphene, or a combination thereof.

10. An electronic device comprising the coating set of claim 9.

11. The coating set of claim 9, wherein the adhesive layer has a thickness of from about 5 μm to about 30 μm.

12. The coating set of claim 9, wherein the first thermally conductive layer and the second thermally conductive layer each have a thickness of about 5 μm to about 500 μm.

3. The coating set of claim 9, wherein the first oxide layer and the second oxide layer each have a thickness of about 3 μm to about 15 μm.

14. The coating set of claim 9, wherein the aluminum foil layer has a thickness of about 10 μm to about 100 μm.

15. A method of making an electronic device cover including a substrate, the method comprising:
applying an adhesive layer on a surface of the substrate:
applying a first thermally conductive layer on the adhesive layer;
applying a first oxide layer on the first thermally conductive layer;
applying an aluminum foil layer on the first oxide layer;
applying a second oxide layer on the aluminum foil layer;
applying a second thermally conductive layer on the second oxide layer; and
applying a thermoplastic polymer layer on the second thermally conductive layer.
